(19) United States
(12) Patent Application Publication
(10) Pub. No.: US 2019/0189394 A1
(43) Pub. Date: Jun. 20, 2019

(54) METHOD FOR IMPLANTING IONS ON A SURFACE OF AN OBJECT TO BE TREATED AND INSTALLATION FOR IMPLEMENTING THIS METHOD

(71) Applicant: The Swatch Group Research and Development Ltd, Marin (CH)

(72) Inventors: Csilla Miko, Essertines-sur-Yverdon (CH); Pierry Vuille, Les Emibois (CH); Jean-Luc Bazin, Tuescherz-Alfermee (CH); Arne Kool, Blonay (CH); Alexis Boulmay, Morteau (FR)

(73) Assignee: The Swatch Group Research and Development Ltd, Marin (CH)

(21) Appl. No.: 16/210,004

(22) Filed: Dec. 5, 2018

(30) Foreign Application Priority Data
Dec. 20, 2017 (EP) 17209168.8

(51) Int. Cl. H01J 37/317; H01J 37/08; H01J 37/32; H01J 37/18

(52) U.S. Cl. CPC H01J 37/3171; H01J 37/18; H01J 37/32678; H01J 37/08

(57) ABSTRACT

A method for the implantation of mono- or multi-charged ions on a surface of an object to be treated placed in a vacuum chamber, wherein this method includes the step that consist simultaneously of: injecting into the vacuum chamber a beam of ions produced by a source of ions and directing this beam of ions towards the surface of the object to be treated, and illuminating the surface of the object to be treated with a source of ultraviolet radiation producing ultraviolet radiation that propagates in the vacuum chamber. An ion implantation installation for implementing the implantation method.

### TECHNICAL FIELD OF THE INVENTION

The subject matter of the present invention is a method of ion implantation in the surface of an object to be treated, in particular but not exclusively an object made from synthetic sapphire, by means of a beam of ions. This method aims to increase the number of ions that it is possible to implant in the surface of the object to be treated and the depth at which these ions can penetrate into the object. The present invention can apply either to a solid object or to an object in a powder state formed by metal particles or ceramic particles.

### TECHNOLOGICAL BACKGROUND OF THE INVENTION

Ion implantation methods consist of bombarding the surface of the object to be treated, for example by means of a source of mono- or multi-charged ions of the electron cyclotron resonance type or ECR.

An ECR ion source uses cyclotron resonance of the electrons in order to create a plasma. Microwaves are injected into a volume of gas at low pressure intended to be ionised, at a frequency corresponding to the electron cyclotron resonance defined by a magnetic field applied to a region situated inside the volume of gas to be ionised. The microwaves heat the free electrons present in the volume of gas to be ionised. These free electrons, under the effect of the thermal agitation, will come into collision with the atoms or molecules and cause ionisation thereof. The ions produced correspond to the type of gas used. This gas may be pure or a compound. It may also be a vapour obtained from a solid or liquid material. The ECR ion source is able to produce singly charged ions, that is to say ions whose degree of ionisation is equal to 1, or multicharged ions, that is to say ions whose degree of ionisation is greater than 1.

By way of example, a source of multicharged ions of the electron cyclotron resonance ECR type is illustrated in FIG. 1 appended to the present patent application. Highly schematically, an ECR source of singly or multicharged ions, designated overall by the general numerical reference 1, comprises an injection stage 2 into which a volume 4 of gas to be ionised and a microwave 6 are introduced, a magnetic confinement stage 8 in which a plasma 10 is created, and an extraction stage 12 that makes it possible to extract and accelerate the ions of the plasma 10 by means of an anode 14a and a cathode 14b between which a high voltage is applied.

The appearance of the beam of ions 16 produced at the output of the ECR ion source 1 is illustrated in FIG. 2 appended to the present patent application.

One of the problems encountered with the ion implantation method briefly described above lies in the fact that, as the ions penetrate the surface of the object to be treated, they create an electrostatic potential barrier that tends to slow down the ions that arrive subsequently, which limits the depth of penetration of these ions under the surface of the object to be treated. This is because, the more numerous the ions to be implanted on the surface of the object to be treated, the stronger the electrostatic field that these ions create, and the more the surface of the object to be treated tends to repel the ions that arrive from the ECR ion source, which poses problems of homogeneity in the method of ion implantation of the object to be treated. In the case where the object to be treated is electrically conductive, this problem is less present since at least some of the free electrons or those weakly bound to the material in which the object to be treated is produced can recombine with the implanted ions. On the other hand, in the case where the object to be treated is produced from a material that does not conduct electricity, the phenomenon of recombination between electrons and mono- or multi-charged ions does not occur, and guaranteeing a homogeneous distribution of the ions in the surface of the object to be treated is practically impossible.

### SUMMARY OF THE INVENTION

The aim of the present invention is to solve the problems mentioned above as well as others by providing a method for implanting ions on the surface of object to be treated, making it possible in particular to guarantee homogeneous distribution of these ions on the surface of the object.

To this end, the present invention relates to a method for implanting ions on a surface of an object to be treated placed in a vacuum chamber, this method comprising the step that consists simultaneously of:
directing, towards the surface of the object to be treated, a beam of ions produced by a source of ions, and
illuminating the surface of the object to be treated by means of a source of ultraviolet radiation that propagates in the vacuum chamber.

Owing to these features, the present invention provides a method for the surface treatment of an object in which the object to be treated, placed in a vacuum chamber, is illuminated by means of a source of ultraviolet light at the same time as this object is bombarded by means of a beam of ions. This method thus guarantees more homogeneous distribution of the ions on the surface of the object to be treated, just as it enables these ions to penetrate more deeply under the surface of the object to be treated. It will be understood in fact that, despite the fairly high vacuum that prevails in the vacuum chamber, there nevertheless remains in the atmosphere of the vacuum chamber atoms and molecules from which the photons of the ultraviolet radiation will extract electrons that will be attracted by the positive potential of the surface of the object to be treated and will recombine with the ions present on the surface of the object so as to cancel out the electrostatic charges. Resulting from the recombination between the free electrons that are situated in the vacuum chamber and the ions implanted on the surface of the object to be treated, the electrostatic potential of the object to be treated can be maintained at sufficiently low values to interfere as little as possible with the implantation of new ions and to enable them to penetrate sufficiently deeply under the surface of the object to be treated.

According to one embodiment of the invention, the atmospheric pressure inside the vacuum chamber is between 10⁴ and 10⁻⁴ Pa, preferably between 10⁻² Pa and 10⁻⁴ Pa.

According to one embodiment of the invention, a gas such as a noble gas is injected into the vacuum chamber. Indeed, because of the fairly high vacuum that prevails in the vacuum chamber in which the object to be treated is placed, it has been found that the atoms and molecules in this rarefied atmosphere are not always sufficient in number to guarantee satisfactory implementation of the method according to the invention. This is why, by way of variant, provision is made for enriching the atmosphere in the vacuum chamber with a noble gas so that the phenomenon of ionisation of this atmosphere produces electrons in greater quantities.

The invention also relates to an installation for implanting mono- or multi-charged ions in a surface of an object to be treated, this installation comprising a vacuum chamber in which the object to be treated is disposed, the installation also comprising a source of ions that injects a beam of ions into the vacuum chamber, this beam of ions being directed towards the surface of the object to be treated, the installation also comprising a source of ultraviolet radiation producing an ultraviolet radiation that propagates in the vacuum chamber and illuminates the object to be treated, the source of ions and the source of ultraviolet radiation being arranged to function simultaneously.

### BRIEF DESCRIPTION OF THE FIGURES

Other features and advantages of the present invention will emerge more clearly from the following detailed description of an example embodiment of the method according to the invention, this example being given purely by way of illustration and in a non-limiting manner in relation to the accompanying drawing, on which:

FIG. 1, already cited, is a schematic view of a source of ions of the electron cyclotron resonance ECR type according to the prior art;

FIG. 2, already cited, is a schematic view that illustrates a beam of ions at the exit of the source of ions of the electron cyclotron resonance ECR type illustrated in FIG. 1;

FIG. 3 is a schematic view of an installation for implanting mono- or multi-charged ions on the surface of the object to be treated according to the invention, and

FIG. 4 is a view to a larger scale of the region surrounded by a circle in FIG. 3 that illustrates the phenomenon of recombination of the free electrons that are situated in the atmosphere of the vacuum chamber with the ions present on the surface of the object to be treated.

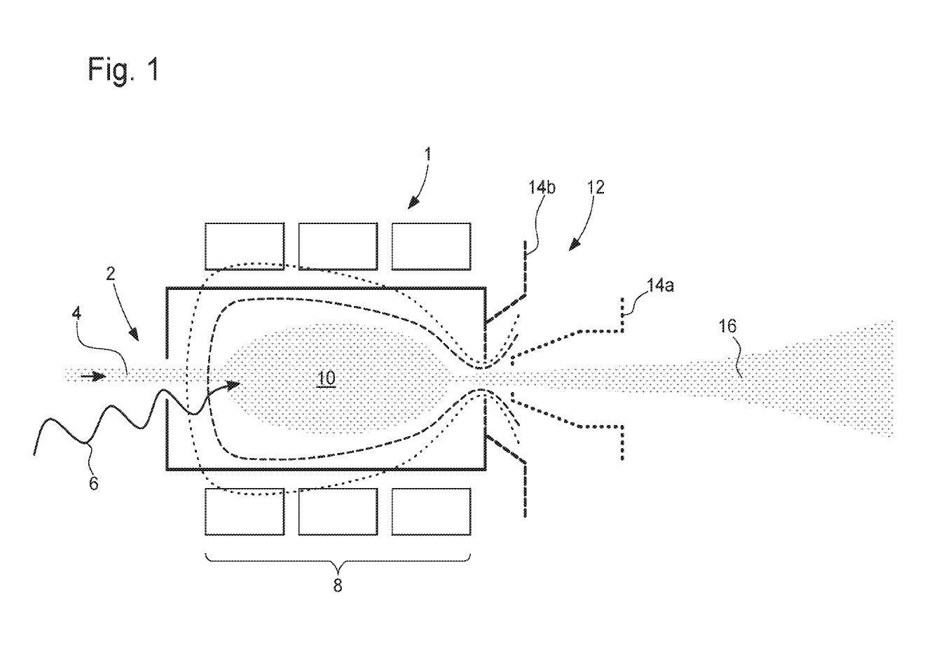

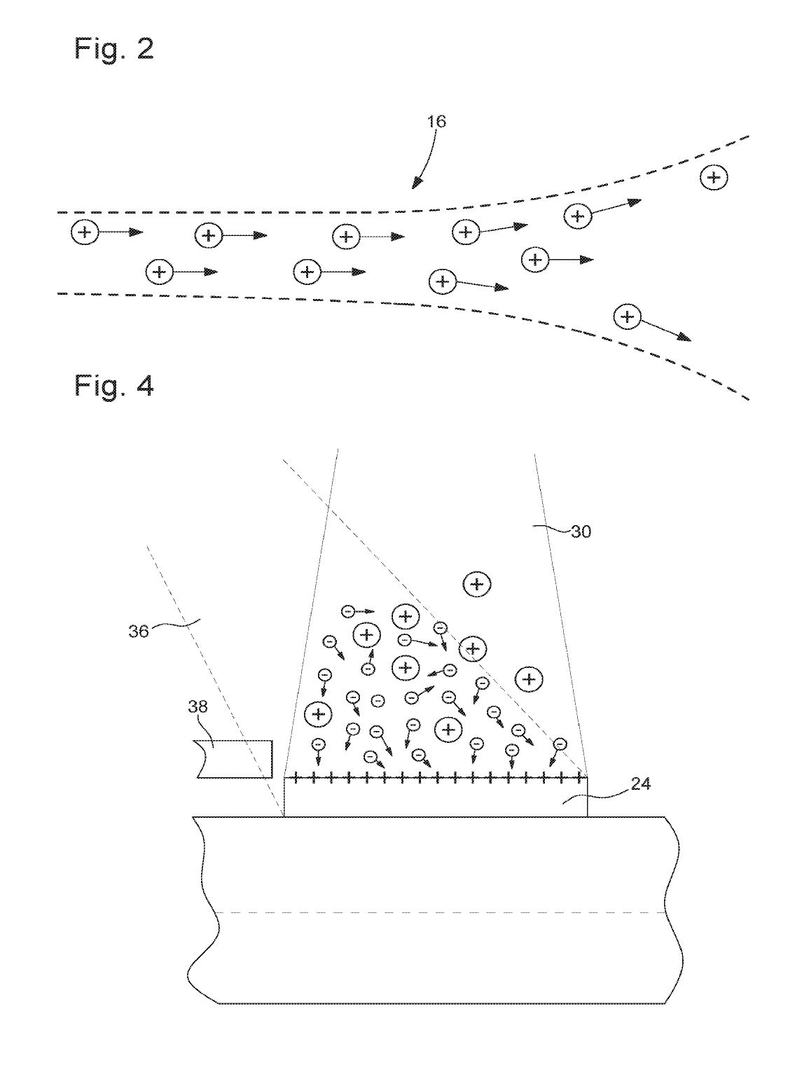

### DETAILED DESCRIPTION OF AN EMBODIMENT OF THE INVENTION

The present invention proceeds from the general inventive idea that consists of placing an object subjected to a process of ion implantation in a vacuum chamber and illuminating it by means of ultraviolet radiation at the same time as it is bombarded with a beam of mono- or multi-charged ions. In propagating in the vacuum chamber, the protons of the ultraviolet radiation extract electrons from the atoms and molecules that remain in the rarefied atmosphere of the vacuum chamber, these free electrons next recombining with the ions present on the surface of the object the surface of which is being treated. It is thus possible to control the surface potential of the object to be treated and to maintain this potential at a sufficiently low level for the new ions that arrive not to be excessively slowed down by the potential barrier and to keep sufficient kinetic energy enabling them to penetrate in depth into the object to be treated.

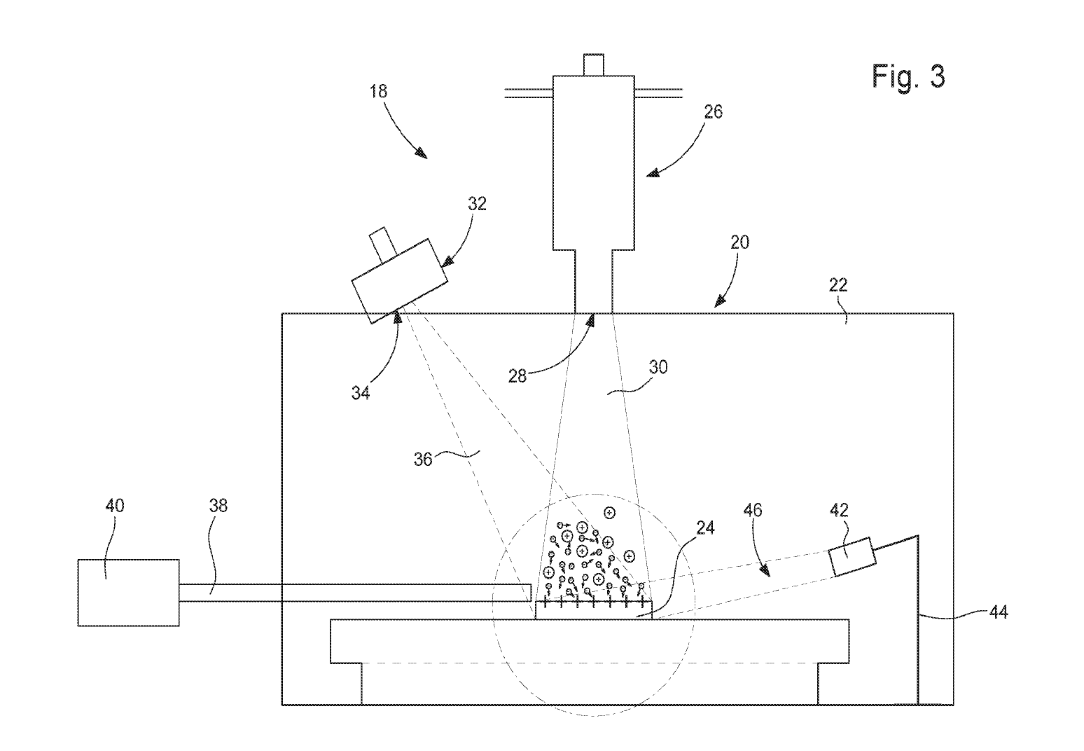

An ion implantation installation enabling the method according to the invention to be implemented is shown schematically in FIG. 3. Designated overall by the numerical reference 18, this ion implantation installation comprises a vacuum chamber 20 in the sealed enclosure 22 of which an object 24 intended to be subjected to an ion implantation process is placed. The object 24 to be treated may be solid or be in the powder state. It may be an amorphous or crystalline material, insulating or electrically conductive, metal or ceramic. In the case where the object 24 to be treated is in the powder state, it will preferentially be stirred throughout the ion implantation process in order to ensure that the particles that make up this powder are exposed homogeneously to the ion implantation beam.

A source of ions 26, for example of the electron cyclotron resonance ECR type, is sealingly fixed to the enclosure 22 of the vacuum chamber 20, facing a first opening 28 provided in this enclosure 22. This source of ions 26, of a type similar to that of the ECR source of ions described above, is oriented so that the beam of mono- or multi-charged ions 30 that it produces propagates in the vacuum chamber 20 and strikes the surface of the object 24 to be treated. The mono- or multi-charged ions that strike the object to be treated 24 penetrate more or less deeply under the surface of the object 24 and accumulate progressively, thus giving rise to an electrostatic potential barrier that tends to restrict and repel the ions that arrive subsequently, which poses problems of non-homogeneity of the distribution of the ions on and under the surface and in the thickness of the object 24 to be treated.

To remedy this problem, a source of ultraviolet radiation 32 is also mounted sealingly on the enclosure 22 of the vacuum chamber 20, facing a second opening 34 provided in the enclosure 22. This source of ultraviolet radiation 32 is oriented so that the ultraviolet radiation 36 that it produces propagates in the vacuum chamber 20 and falls onto the surface of the object to be treated 24 at the same time as the beam of ions 30 strikes the surface of the same object to be treated 24.

The vacuum that prevails in the sealed enclosure 22 of the vacuum chamber 20 is relatively high, typically between 10⁴ and 10⁻⁴ Pa, preferably between 10⁻² Pa and 10⁻⁴ Pa. Nevertheless, despite the very high vacuum that prevails in the vacuum chamber 20, there remain in the atmosphere of this vacuum chamber 20 atoms and molecules from which the photons of the ultraviolet radiation 36 will extract electrons that will be attracted by the positive potential of the surface of the object 24 and will recombine with the ions present on the surface of this object 24, so as to cancel out the electrostatic charges. The electrostatic potential of the object to be treated 24 can thus be maintained at sufficiently low values to interfere with the implantation of new ions as little as possible and to enable them to penetrate sufficiently deeply below the surface of the object to be treated 24.

In order to improve the process of implantation of ions in the object to be treated 24, enriching the atmosphere of the vacuum chamber 20 can be envisaged. For this purpose, the vacuum chamber 20 is provided with an inlet valve 38 to which a source of gas 40 is connected, for example a noble gas such as argon or xenon. This inlet valve 38 emerges close to the object to be treated 24, so as to create locally, in the vicinity of the object to be treated 24, a slight overpressure of noble gas richer in atoms.

By proceeding in this way, the atmosphere of the vacuum chamber 20 is enriched and the number of electrons extracted from the atoms present in the atmosphere that prevails in the vacuum chamber 20 (see FIG. 4) is increased. The process of recombination between the electrons in the vacuum chamber 20 and the ions on the surface of the object to be treated 24 is therefore amplified, which makes it possible to reduce even further the electrical potential of the object to be treated. This is because it has been realised with a certain amount of surprise that the electrons extracted by the photons of the ultraviolet radiation from the atoms of the noble gas, although they partly recombine with ionised atoms of the noble gas, or even with the ions of the ion implantation beam, all the same recombine in a sufficiently large number with the positive charges present on the surface of the object to be treated in order to substantially reduce the electrostatic potential of the surface of the object to be treated.

In order to improve further the process of implantation of ions in the object to be treated 24, providing a second source of ultraviolet radiation 42 can be envisaged. This second source of ultraviolet radiation 42 can be fixed sealingly to the enclosure 22 of the vacuum chamber 20, or be directly installed inside the vacuum chamber 20 while being supported by a foot 44. The second source of ultraviolet radiation 42 can be oriented so that the ultraviolet radiation 42 that it emits forms an angle, for example of approximately 90°, with respect to the ultraviolet radiation 36 emitted by the first source of ultraviolet radiation 32. With such an arrangement of the sources of ultraviolet radiation 32, 42, it is possible to treat larger objects 24.

It goes without saying that the present invention is not limited to the embodiments that have just been described and that various simple modifications and variants can be envisaged by a person skilled in the art without departing from the scope of the invention as defined by the accompanying claims.

It should be noted in particular that the present invention applies especially to the surface treatment of objects made from sapphire (natural or synthetic) for producing watch glasses. By virtue of the ion implantation method according to the invention, the quantity of incident light reflected by such glasses is significantly reduced, which significantly improves the legibility of the information displayed by the indicating devices (hands, date, decoration) situated under these glasses.

The present invention also applies to the surface treatment of crystalline or amorphous metal objects or ceramics, the mechanical properties of which, in particular scratch resistance, are greatly improved when the ion implantation method with neutralisation of charges according to the invention is applied thereto.

The present invention also applies to the surface treatment of particles of a metal or ceramic material in the powder state. The metal or ceramic powder particles obtained by means of the method according to the invention are intended for the manufacture of solid parts by means of powder metallurgy methods such as the injection moulding method, better known by its English name metal injection moulding or MIM, pressing or additive manufacture such as three-dimensional laser printing.

According to particular embodiments of the method according to the invention:
the source of mono- or multi-charged ions is of the electron cyclotron resonance ECR type;
the ions are accelerated at a voltage of between 15,000 volts and 40,000 volts;
the material from which the beam of ions is produced is chosen from nitrogen N, carbon C, oxygen O, argon Ar, helium He and neon Ne;

the dose of ions implanted is between 1*10¹⁴ ions·cm⁻² and 7.5.10¹⁷ ions·cm⁻², and preferably between 1*10¹⁶ ions·cm⁻² and 15*10¹⁶ ions·cm⁻²; the depth of implantation of the ions is 150 nm to 250 nm;
the metal material is a precious metal chosen from gold and platinum;
the metal material is a non-precious metal chosen from magnesium, titanium and aluminium;
the particles of the metal or ceramic powder are stirred throughout the ion implantation process;
the granulometry of the particles of the metal powder or ceramic used is such that substantially 50% of all these particles have a dimension of less than 2 micrometres, the dimension of the particles of the metal or ceramic powder used not exceeding 60 micrometres;
the ceramic material treated according to the ion implantation method in accordance with the present invention is a carbide, in particular a titanium carbide TiC or a silicon carbide SiC;
the ceramic material of the carbide type is bombarded by means of nitrogen atom ions N in order to form a carbonitride, in particular titanium carbonitride TiCN or silicon carbonitride SiCN;
the ceramic material treated according to the ion implantation method according to the invention is a nitride, in particular a silicon nitride Si₃N₄;
the ceramic material treated according to the ion implantation method in accordance with the present invention is an oxide, in particular zirconia ZrO₂ or alumina Al₂O₃;
the ceramic material of the oxide type is bombarded by means of nitrogen ions in order to form an oxynitride, in particular zirconium oxynitride ZrO(NO₃)₂, or even zirconium nitride ZrN if the ion bombardment is prolonged for sufficiently long, or aluminium oxynitride AlOₓN_{y};
the ceramic material of the oxide type is bombarded by means of carbon ions in order to form a carbonitride, in particular zirconium oxycarbide ZrO₂C, or even zirconium carbide ZrC;
the ceramic material of the oxide type is bombarded by means of boron ions in order to form an oxyboride, in particular zirconium oxyboride ZrO₂B, or even zirconium boride ZrB₂ if the ion bombardment is prolonged for sufficiently long.

### LIST OF NAMES

1. Source of ions of the electron cyclotron resonance ECR type
2. Injection stage
4. Volume of gas to be ionised
6. Microwave
8. Magnetic confinement stage
10. Plasma
12. Extraction stage
14a. Anode
14b. Cathode
16. Beam of mono- or multi-charged ions
18. Ion implantation installation
20. Vacuum chamber
22. Sealed enclosure
24. Object to be treated
26. Source of ions
28. First opening
30. Beam of mono- or multi-charged ions
32. Source of ultraviolet radiation
34. Second opening
36. Ultraviolet radiation
38. Inlet valve
40. Gas source
42. Second source of ultraviolet radiation
44. Foot
46. Ultraviolet radiation

1. A method for implanting mono- or multi-charged ions on a surface of an object to be treated placed in a vacuum chamber, this method comprising the step that consists simultaneously of:
injecting into the vacuum chamber a beam of ions produced by a source of ions and directing this beam of ions towards the surface of the object to be treated, and
illuminating the surface of the object to be treated by means of a source of ultraviolet radiation producing ultraviolet radiation that propagates in the vacuum chamber.

2. The method according to claim 1, wherein the source of ions is of the electron cyclotron resonance type.

3. The method according to claim 1, wherein a gas is injected into the vacuum chamber during the ion implantation process.

4. The method according to claim 2, wherein a gas is injected into the vacuum chamber during the ion implantation process.

5. The method according to claim 3, wherein the injected gas is a noble gas.

6. The method according to claim 4, wherein the injected gas is a noble gas.

7. The method according to claim 1, wherein the atmospheric pressure inside the vacuum chamber is between 10⁴ and 10⁻⁴ Pa and preferably between 10⁻² Pa and 10⁻⁴ Pa.

8. The method according to claim 2, wherein the atmospheric pressure inside the vacuum chamber is between 10⁴ and 10⁻⁴ Pa and preferably between 10⁻² Pa and 10⁻⁴ Pa.

9. The method according to claim 3, wherein the atmospheric pressure inside the vacuum chamber is between 10⁴ and 10⁻⁴ Pa and preferably between 10⁻² Pa and 10⁻⁴ Pa.

10. The method according to claim 4, wherein the atmospheric pressure inside the vacuum chamber is between 10⁴ and 10⁻⁴ Pa and preferably between 10⁻² Pa and 10⁻⁴ Pa.

11. The method according to claim 5, wherein the atmospheric pressure inside the vacuum chamber is between 10⁴ and 10⁻⁴ Pa and preferably between 10⁻² Pa and 10⁻⁴ Pa.

12. The method according to claim 6, wherein the atmospheric pressure inside the vacuum chamber is between 10⁴ and 10⁻⁴ Pa and preferably between 10⁻² Pa and 10⁻⁴ Pa.

13. The method according to claim 1, wherein the surface of the object to be treated is illuminated by means of a second source of ultraviolet radiation producing a second ultraviolet radiation that propagates in the vacuum chamber in a direction forming an angle with the first ultraviolet radiation.

14. The method according to claim 1, wherein the object to be treated is produced from a material that does not conduct electricity or is semiconductive.

15. The method according to claim 14, wherein the material from which the object to be treated is produced is chosen from the group formed by natural and synthetic sapphires, mineral glasses, polymers and ceramics.

16. The method according to claim 1, wherein the material from which the object to be treated is produced is an electrically conductive material.

17. The method according to claim 16, wherein the material from which the object to be treated is produced is chosen from the group formed by crystalline or amorphous metal alloys, ceramics and precious and non-precious metals.

18. The method according to claim 1, wherein the atoms that are implanted in the surface of the object to be treated by means of the source of ions are chosen from the group formed by nitrogen N, carbon C, oxygen O, argon Ar, helium He and neon Ne.

19. The method according to claim 1, wherein the surface of the object to be treated is treated by means of an ion implantation dose that is situated in a range lying between 1*10¹⁴ ions·cm⁻² and 7.5·10¹⁷ ions·cm⁻², and preferably between 1*10¹⁶ ions·cm⁻² and 15*10¹⁶ ions·cm⁻², and wherein the acceleration voltage of the ions is between 7.5 kV and 40 kV.

20. An installation for the implantation of mono- or multi-charged ions in a surface of an object to be treated, wherein this installation comprises a vacuum chamber in which the object to be treated is disposed, wherein the installation also comprises a source of ions that injects a beam of ions into the vacuum chamber, wherein this beam of ions is directed towards the surface of the object to be treated, wherein the installation also comprises a source of ultraviolet radiation that produces ultraviolet radiation that propagates in the vacuum chamber and illuminates the object to be treated, wherein the source of ions and the source of ultraviolet radiation are arranged to function simultaneously.

21. The installation for the implantation of mono- or multi-charged ions according to claim 20, wherein the source of ions is of the electron cyclotron resonance type.

22. The installation for the implantation of mono- or multi-charged ions according to claim 20, wherein the installation comprises a source of gas that delivers gas into the vacuum chamber via an inlet valve to which the source of gas is connected.

23. The installation for the implantation of mono- or multi-charged ions according to claim 21, wherein the installation comprises a source of gas that delivers gas into the vacuum chamber via an inlet valve to which the source of gas is connected.

24. The installation for the implantation of mono- or multi-charged ions according to claim 22, wherein the gas contained in the source of gas is a noble gas.

25. The installation for the implantation of mono- or multi-charged ions according to claim 20, wherein the installation produces an ion implantation dose in a range lying between 1*10¹⁴ ions·cm⁻² and 7.5·10¹⁷ ions·cm⁻², and preferably between 1*10¹⁶ ions·cm⁻² and 15*10¹⁶ ions·cm⁻², and wherein the acceleration voltage of the ions is between 7.5 kV and 40 kV.

26. The installation for the implantation of mono- or multi-charged ions according to claim 20, wherein the atmospheric pressure inside the vacuum chamber is between 10⁴ Pa and 10⁻⁴ Pa and preferably between 10² Pa and 10⁻⁴ Pa.

27. The installation for the implantation of mono- or multi-charged ions according to claim 20, wherein the installation comprises a second source of ultraviolet radiation that illuminates the surface of the object to be treated with a second ultraviolet radiation that propagates in the vacuum chamber in a direction forming an angle with the first ultraviolet radiation.
